(19) United States
(12) Patent Application Publication
(10) Pub. No.: US 2004/0040931 A1
(43) Pub. Date: Mar. 4, 2004

(54) Plasma processing method and plasma processor

(76) Inventors: Akira Koshiishi, Nirasaki-Shi (JP); Shinji Himori, Nirasaki-Shi (JP)

Correspondence Address: SMITH, GAMBRELL & RUSSELL, LLP, 1850 M STREET, N.W., SUITE 800, WASHINGTON, DC, 20036, US

(21) Appl. No.: 10/451,852

(22) PCT Filed: Dec. 20, 2001
(86) PCT No.: PCT/JP01/11207

(30) Foreign Application Priority Data
Dec. 26, 2000 (JP) 2000-395138

(51) Int. Cl. H01L 21/306

(52) U.S. Cl. 216/67; 156/345.43

(57) ABSTRACT

A plasma processing system comprises a pair of electrodes (12, 13) arranged in parallel to each other in a processing vessel (11), and a focus ring (17) arranged on one (12) of the electrodes for holding an object to be processed (8) and surrounding the object on the electrode (12). A plasma processing method for processing the object with the plasma, applying a high frequency power to the electrodes of the system to generate the plasma between the pair of electrodes, is carried out as follows. First, a focus ring having a certain material, dimension and shape is used for carrying out the plasma processing on certain processing conditions. Then, on the basis of the results of this plasma processing, if the processing rate on the outer peripheral region of the object is lower (higher) than the processing rate on the central region thereof, a new focus ring having at least one of changed material, dimension and shape is prepared so as to increase (decrease) impedance and/or relative dielectric constant of the focus ring. Then, the prepared new focus ring is used for carrying out another plasma processing on the same processing conditions.

### TECHNICAL FIELD

The present invention relates generally to a plasma processing system having a pair of electrodes arranged in parallel to each other, and a plasma processing method using such a system. More specifically, the invention relates to the improvement of uniformity of a plasma processing to an object to be processed.

### BACKGROUND ART

For example, as shown in FIG. 15, a conventional plasma processing system comprises a bottom electrode 1 arranged in a processing vessel (not shown) so as to be movable in vertical directions, and a top electrode 2 arranged so as to face the bottom electrode 1 in parallel thereto. To these electrodes 1 and 2, high frequency powders having different frequencies are applied from first and second high frequency power supplies 3 and 4 via matching devices 3A and 4A, respectively. Thus, plasma is generated between the electrodes 1 and 2 to etch a silicon oxide film on the surface of a wafer 8 serving as an object to be processed. In the outer peripheral portion of the top face of the bottom electrode 1, a focus ring 5 surrounding the wafer 8 is arranged. The focus ring 5 serves to condense the plasma generated between the electrodes 1 and 2 on the wafer 8. On the outer periphery of the top electrode 2, a shield ring 6 is mounted as will be described later.

By the way, in the case of the conventional plasma processing system, an electric field is formed between the bottom electrode 1 and the top electrode 2 when a plasma processing such as etching is carried out. However, a portion of the bottom electrode 1 supporting thereon the wafer is electrically discontinuous from another portion of the bottom electrode 1 supporting thereon the focus ring 5, so that circuits for the high frequency power supplies 3 and 4 are not equivalent to each other. Thus, a difference in field intensity between the outer peripheral region and central region of the wafer is caused due to the influence of the focus ring 5. Therefore, there is a problem in that the etch rate on the outer peripheral region of the wafer is relatively deteriorated to make the etch rate ununiform.

Therefore, various measures to prevent the turbulence of the electric field in the bottom electrode have been proposed. For example, Japanese Patent Application No. 6-168911 has proposed a semiconductor producing system wherein a peripheral ring for changing the density distribution of reactive ions is provided on the periphery of a bottom electrode. Japanese Patent Application No. 63-229719 has proposed a dry etching system wherein a height adjustable auxiliary ring plate surrounding the outer periphery of a wafer is provided. Japanese Patent application No. 5-335283 has proposed a plasma processing method wherein a conductive ring is provided on a bottom electrode in the vicinity of the peripheral edge of a wafer to be conducted to the bottom electrode or to be controlled so as to substantially have the same potential as that of the bottom electrode.

However, even if the uniformity of the field intensity can be improved by these measures, the uniformity of ±10% can be achieved at most. Therefore, the difference in field intensity between the outer peripheral region and central region of the wafer 8 due to the influence of the focus ring 5 can not sufficiently be eliminated. That is, there is the remaining problem in that the etch rate is ununiform on the outer peripheral region and central region of the wafer 8.

As is not shown in FIG. 15, the top electrode 2 has an electrode member, and a supporting body supporting thereon the electrode member. In this case, the electrode member is secured to the supporting body by means of a screw of stainless or the like. The shield ring 6 is mounted on the top electrode 2 for protecting such a screw from plasma and for associating with the focus ring 5 to condense plasma on the wafer 8. The shield ring 6 is formed of an insulating material of an inorganic oxide, such as quarts, so as not to generate contaminants during etching.

However, in the case of a plasma processing system wherein the shield ring 6 is formed of, e.g. quarts, there is the following problem. That is, it was found that if a silicon oxide film of the wafer 8 is etched with a fluorocarbon gas (CₓF_{y}) via a resist film so as to have a specific pattern, the etch rate of the resist film on the outer peripheral region of the wafer 8 is higher than that of the central region thereof so that the etch rate of the resist film is ununiform as shown in FIG. 16.

At this time, as shown in FIG. 16, the distance between the electrodes 1 and 2 was changed in three stages from 21 mm to 35 mm, and the etch rate of the resist film at each distance was measured. As a result, in all cases, the etch rate suddenly rises on the outer peripheral region of the wafer 8, so that the etch rate of the resist film is ununiform. If the etch rate of the resist film is ununiform, the etching dimension and shape for the silicon oxide film is shifted from target dimension and shape.

As another conventional plasma processing system, there is known a system wherein a magnetic field fed into a processing space is rotated to make a plasma density and a self-bias voltage uniform. In this system, it is possible to apparently make plasma uniform, but it is required to provide a mechanism for rotating a magnetic field, so that there is a problem in that it is difficult to decrease the size of the plasma system.

In recent years, there has been also proposed a plasma processing system, the size of which is decreased by making plasma uniform without rotating a magnetic field. As shown in FIG. 17, this system has a top electrode 220 having a conductive top ring electrode 224. A magnet arranged around a processing vessel generates a uniform magnetic field parallel to a surface to be processed of a wafer, and high frequency voltages of, e.g. 100 MHz, are supplied to feeding points (feed points on north (N) side 231, south (S) side 232, east (E) side 233 and west (W) side 234) corresponding to four poles of the magnetic field to generate an electric field. That is, in the vicinity of the bottom face of the top ring electrode 224, charged particles in plasma are drifted from the W-side to the E-side on the opposite direction to the E×B drift direction on the wafer, so as to make plasma uniform between the W-side and the E-side.

However, in this plasma processing system, with respect to the horizontal magnetic field formed by the magnet arranged around the processing vessel, the magnetic flux density is relatively high on the E-side and is relatively low on the W-side. Therefore, there is a problem in that the E×B drift effect of electrons from the W-side to the E-side in the vicinity of the bottom face of the top ring electrode 224 is deteriorated.

### DISCLOSURE OF THE INVENTION

It is therefore a principal object of the present invention to eliminate the above described problems and to provide a plasma processing method capable of decreasing a difference in field intensity between the outer peripheral and central regions of an object to be processed due to the influence of a focus ring and capable of uniformly applying a plasma processing to the object.

The inventor has studied various plasma processing conditions and found that it is possible to decrease the difference in field intensity between the outer peripheral and central regions of the object by using the focus ring of a specific material, dimension and/or shape in accordance with processing conditions.

The present invention has been made on the basis of this knowledge, and provides a plasma processing method for processing an object to be processed with a plasma in a plasma processing system, the system comprising a pair of electrodes arranged in parallel to each other in a processing vessel, the object being held on one of the electrodes and surrounded by a focus ring provided on the one of the electrodes, the system producing the plasma between the pair of electrodes by applying a high frequency power to at least one of the electrodes, the plasma processing method comprising the steps of:

(a) carrying out a plasma processing on certain processing conditions with the focus ring having a certain material, dimension and shape;

(b) preparing a new focus ring wherein at least one of the material, dimension and shape is changed on the basis of results of the plasma processing so that,

(b-1) if a processing rate on an outer peripheral region of the object is lower than a processing rate on a central region of the object, an impedance and/or a relative dielectric constant of the focus ring is increased in accordance with the difference in the processing rate between the two regions, and

(b-2) if a processing rate on an outer peripheral region of the object is higher than a processing rate on a central region of the object, an impedance and/or a relative dielectric constant of the focus ring is decreased in accordance with the difference in the processing rate between the two regions; and

(c) carrying out another plasma processing on the same processing conditions as those at the step (a) with the prepared new focus ring.

According to this plasma processing method, it is possible to reduce the difference in field intensity between the outer peripheral and central regions of the object due to the influence of the focus ring, so that it is possible to uniformly process the object with the plasma.

It is a second object of the present invention to provide a plasma processing system having the shield ring, the plasma processing system being capable of improving the uniformity of a plasma processing, such as etching, applied to the object.

The inventors have studies various causes for the rise of the etch rate on the outer peripheral region of the resist film when the silicon oxide film is etched by means of the plasma processing system having the shield ring of quarts (SiO₂), and found the following. That is, the shield ring 6 is attacked by ions in the plasma during the etching process. Since the shield ring 6 is formed of quarts, the following reaction occurs by ion attack to produce by-products, such as oxygen, between the electrodes 1 and 2 from SiO₂.

SiO₂+CₓF_{y}→SiF₄↑+CO↑+O₂↑

Particularly, if there is a difference in level between the inner peripheral edge of the shield ring 6 and the electrode members as shown in FIG. 15, this stepped portion is easily sputtered, so that the amount of oxygen emitted from the shield ring 6 increases. It is guessed that the etch rate of the resist film on the outer peripheral region of the wafer 8 is higher than that on the central region thereof due to the influence of oxygen, so that the etch rate of the resist film is ununiform.

Such problems on production of oxygen are common to all of shield rings 6 of inorganic oxides, not only quarts.

The present invention has been made on the basis of this knowledge, and provides a plasma processing system comprising: a processing vessel; a first electrode arranged in the processing vessel; a second electrode, arranged in parallel to the first electrode in the processing vessel, for holding an object to be processed; a high frequency power supply for applying a high frequency power to at least the first electrode; and a shield ring of an inorganic oxide for covering at least an outer peripheral portion of a surface of the first electrode facing the second electrode, the system producing a plasma between the first and second electrodes by applying the high frequency power by the power supply, to process the object with the plasma, wherein a portion of the shield ring contacting the plasma is coated with a plasma-resistant film.

According to this plasma processing system, it is possible to improve the uniformity of the plasma processing applied to the object to be processed in the plasma processing system having the shield ring of the inorganic oxide.

The present invention also provides a plasma processing system for processing an object to be processed having a thin film coated with a resist film, the system etching the thin film in accordance with a shape of the resist film and comprising: a processing vessel; a first electrode arranged in the processing vessel; a second electrode, arranged in parallel to the first electrode in the processing vessel, for holding the object; a high frequency power supply for applying a high frequency power to at least the first electrode; and a shield ring of an inorganic oxide for covering at least an outer peripheral portion of a surface of the first electrode facing the second electrode, the system producing a plasma between the first and second electrodes by applying the high frequency power by the power supply, to etch the object with the plasma, wherein a portion of the shield ring contacting the plasma is coated with a plasma-resistant film.

According to this plasma processing system, it is possible to uniformly etch the resist film to improve the uniformity of etching to the thin film in the plasma processing system having the shield ring of the inorganic oxide.

It is a third object of the present invention to provide a small plasma processing system capable of uniformly increasing the density of plasma by enhancing the E×B drift effect from the W-side to the E-side in the vicinity of the bottom face of a top electrode.

In order to accomplish this problem, the present invention provides a plasma processing system comprising: a processing vessel; a first electrode arranged in the processing vessel, the first electrode including a central electrode electrically grounded, and a high frequency electrode surrounding an outer periphery of the central electrode, a second electrode, arranged in parallel to the first electrode in the processing vessel, for holding an object to be processed having a surface to be processed; magnetic-field applying means for forming a magnetic field between the first and second electrodes, the magnetic field being parallel to the surface of the object and having a certain polarity; and a high frequency power supply for applying a high frequency power to at least the high frequency electrode of the first electrode, wherein a feeding from the high frequency power supply to the high frequency electrode is carried out only at a feeding point on a west side of the magnetic field on the high frequency electrode.

According to this plasma processing system, since the electric field formed on the W-side of the high frequency electrode of the first electrode is stronger than those on other polar sides, it is possible to compensate for a relatively low magnetic field on the W-side formed by the magnetic field applying means. Thus, it is possible to improve the E×B drift effect of electrons from the W-side to the E-side in the vicinity of the surface of the object on the high frequency electrode. Therefore, it is possible to provide a small plasma processing system capable of uniformly increasing the density of plasma.

If the above described plasma processing system further comprises a focus ring electrically grounded, the focus ring surrounding an outer periphery of the high frequency electrode of the first electrode, it is possible to improve the uniformity of the processing rate on the outer peripheral region of the object.

In that case, the plasma processing system preferably further comprises: a first insulating member provided between the central and high frequency electrodes of the first electrode; and a second insulating member provided between the high frequency electrode of the first electrode and the focus ring. Thus, since a parasitic capacity is formed in the insulating members, if feeding is carried out only to the W-side feeding point, it is possible to decrease the current and power flowing from the W-side to the downstream side (S, N and E-sides) by the resistance component of the parasitic capacity. As a result, it is possible to generate a relatively strong electric field on the W-side, and it is possible to generate a relatively weak electric field on the downstream sides (S, N and E-sides).

If a plasma-producing and biasing high frequency power is applied to the second electrode, the processing components, such as etchant in plasma, can be efficiently injected into the surface of the object.

### BRIEF DESCRIPTION OF THE DRAWINGS

FIG. 1 is a longitudinally sectional view schematically showing a first preferred embodiment of a plasma processing system according to the present invention;

FIG. 2 is a diagram showing an equivalent circuit of a focus ring shown in FIG. 1;

FIG. 3 is a graph showing an etch-rate distribution in radial directions of wafers when the material of a focus ring is changed to etch the wafer in the plasma processing system shown in FIG. 1;

FIG. 4 is an equivalent circuit diagram showing the relationship between a wafer, a focus ring and a sheath on a bottom electrode in the plasma processing system shown in FIG. 1;

FIG. 5 is a graph showing the relationship between an impedance and a dielectric constant of each material of a focus ring and the uniformity of etch rate when the material of the focus ring is changed;

FIG. 6 is an enlarged view of a shield ring of a top electrode shown in FIG. 1, for explaining the second preferred embodiment of the present invention;

FIG. 7 is a diagram showing a modified example of a top electrode shown in FIG. 6;

FIG. 8 is a schematic longitudinally sectional view showing the construction of a wafer to be etched in the second preferred embodiment, with respect to each kind of (a) through (f);

FIG. 9 is a graph showing etch rates of a resist film while changing the distance between top and bottom electrodes, when etching a silicon oxide film and when a shield ring shown in FIG. 6 is coated with yttrium oxide;

FIG. 10 is the same graph as FIG. 9 when a shield ring shown in FIG. 6 is coated with polyimide film;

FIG. 11 is a sectional view of a third preferred embodiment of a plasma processing system according to the present invention, taken along the direction through W-pole and E-pole of a magnetic field;

FIG. 12 is a plan view showing the construction of a top electrode of the plasma processing system shown in FIG. 11;

FIG. 13 is a diagram showing the result of measurement of a magnetic field distribution formed on a wafer in the plasma processing system shown in FIG. 11;

FIG. 14 is a diagram for explaining the principle that a top electrode in the third preferred embodiment forms an electric field;

FIG. 15 is a block diagram showing an example of a conventional plasma processing system;

FIG. 16 is a graph showing etch rates of a resist film while changing the distance between top and bottom electrodes, when etching a silicon oxide film and when the plasma processing system shown in FIG. 15 is used; and

FIG. 17 is a plan view showing the construction of a top electrode of a conventional plasma processing system.

### BEST MODE FOR CARRYING OUT THE INVENTION

First Preferred Embodiment

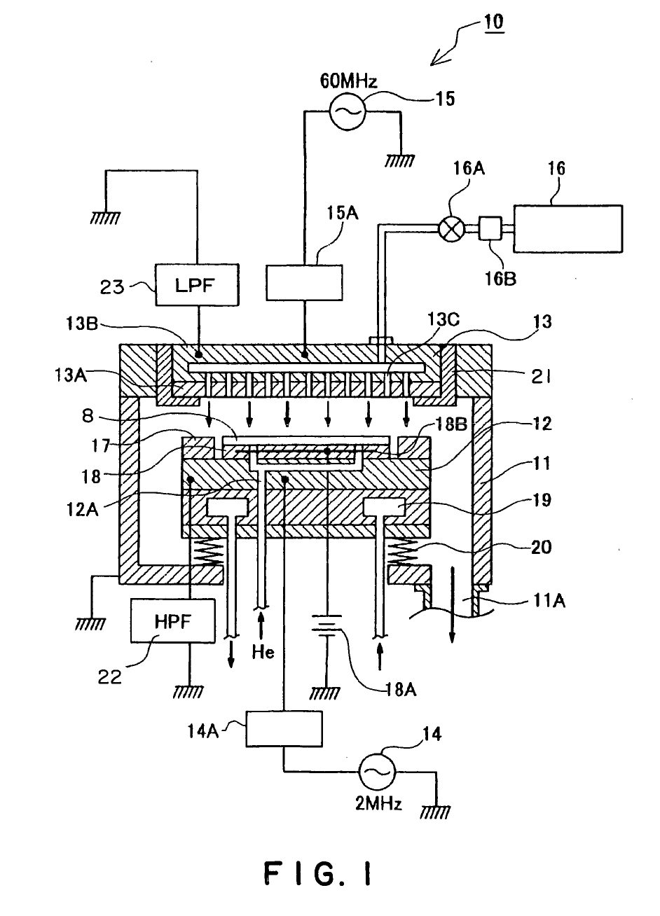

First, referring to FIGS. 1 through 5, the first preferred embodiment of the present invention will be described below.

A plasma processing system for use in a plasma processing method in this preferred embodiment comprises a processing vessel 11 of a conductive material, such as aluminum, as shown in FIG. 1. In the processing vessel 11, a bottom electrode 12 and a top electrode 13 are provided so as to face each other in parallel. The bottom electrode 12 provided in the bottom portion of the processing vessel 11 is formed of aluminum, and is designed to support and hold thereon a wafer 8 serving as an object to be processed. The top electrode 13 provided in the ceiling portion of the processing vessel 11 serves as a process gas supplying member.

The bottom electrode is connected to a first high frequency power supply 14 via a matching device 14A. On the other hand, the top electrode 13 is connected, via a matching device 15A, to a second high frequency power supply 15 for supplying a higher frequency than that of the first high frequency power supply. The top electrode 13 is connected to a gas supply source 16 via a valve 16A and a mass flow controller 16B. Thus, a processing gas, such as fluorocarbon gas, is supplied from the gas supply source 16 to the top electrode 13. In the bottom of the processing vessel 11, an exhaust port 11A is formed. By exhausting the atmosphere interior of the processing vessel 11 by means of an exhaust system (not shown) connected to the exhaust port 11A, the degree of vacuum in the processing vessel 11 can be maintained at a certain degree of vacuum by the processing gas.

For example, while the certain degree of vacuum in the processing vessel 11 is maintained by the processing gas, a first high frequency power of 2 MHz is applied to the bottom electrode 12 from the first high frequency power supply 14, and a second high frequency power of 60 MHz is applied to the top electrode 13 from the second high frequency power supply 15. The second high frequency power generates plasma of the processing gas between the bottom electrode 12 and the top electrode 13, and the first high frequency power generates a bias potential on the bottom electrode 12. Thus, a plasma processing, such as reactive ion etching, can be applied to the wafer 8 on the bottom electrode 12.

On the top face of the bottom electrode 12 on the outer peripheral region thereof, a focus ring 17 surrounding the outer periphery of the wafer 8 is provided. The focus ring 17 serves to condense plasma on the wafer 8. On the top face of the bottom electrode 12, an electrostatic chuck 18 connected to a high DC voltage power supply 18A is provided. The electrostatic chuck 18 is designed to electrostatically attract and hold the wafer 8 by a high DC voltage applied from the high DC voltage power supply 18A. The bottom electrode 12 includes a cooling mechanism 19 and a heating mechanism (not shown). By means of the cooling mechanism 19 and heating mechanism, the temperature of the wafer 8 is adjusted at a certain temperature.

In the bottom electrode 12, a gas passage for passing a gas (e.g. He gas) serving as a heat transfer medium are formed to communicate with a plurality of openings formed on the top face of the bottom electrode 12. The electrostatic chuck 18 is formed with a plurality of holes 18B corresponding to the respective openings communicating with the gas passages 12A. By supplying He gas to a thin gap between the wafer 8 and the electrostatic chuck 18, heat transfer between the bottom electrode 12 and the wafer 8 is promoted. Between the bottom face of the bottom electrode 12 and the bottom face of the processing vessel 11, a bellows 20 of, e.g. aluminum, is provided. By vertically moving the bottom electrode 12 by means of a lifting mechanism (not shown), the distance between the bottom electrode 12 and the top electrode 13 can be suitably set in accordance with the kind of the plasma processing.

The top electrode 13 has a plate-like electrode member 13A, and a hollow supporting body 13B for detachably supporting thereon the electrode member 13A. The electrode member 13A and supporting body 13B have a plurality of dispersed holes 13C, respectively, so that the holes 13C of the electrode member 13A correspond to those of the supporting body 13B. By the holes 13C, the processing gas received by the top electrode 13 from the gas supply source 16 is uniformly dispersed and supplied into the processing vessel 11. In FIG. 1, reference number 22 denotes a high pass filter for filtering a high frequency current entering the bottom electrode 12 from the second high frequency power supply 23, and reference number 23 denotes a low pass filter for filtering a high frequency current entering the top electrode 13 from the first high frequency power supply 14.

By the way, the distribution state of the electric field formed between the bottom electrode 12 and the top electrode 13 by the second high frequency power changes in accordance with the material of the focus ring 17. This is considered to be a phenomenon caused by the change of the facility for the second high frequency current to pass through the focus ring 17 due to the difference in impedance of materials.

That is, if the impedance of the focus ring 17 is high with respect to the high frequency current, it is difficult for the second high frequency current to pass through the focus ring, so that plasma is not generated above the focus ring 17. Therefore, it is possible to inhibit the diffusion of plasma to confine plasma within a range above the wafer 8 to improve the density of plasma on the outer peripheral region of the wafer 8 to increase electron density. Thus, it is possible to relatively improve the etch rate on the outer peripheral region of the wafer 8.

On the other hand, if the impedance of the focus ring 17 is low, the second high frequency current is easy to pass through the focus ring 17, so that plasma is also generated above the focus ring 17. Therefore, plasma is easy to diffuse outwardly in radial directions of the focus ring 17 to decrease plasma density and to decrease the etch rate.

The impedance Z of the focus ring 17 with respect to the high frequency current consists of a resistance (R) component and a reactance (X) component. As expressed by expression (1), the resistance component is defined by the specific resistance ρ of the material of the focus ring 17, and the projected area S and length (thickness) d in an axial direction thereof. As expressed by expression (2), the reactance component is defined by a relative dielectric constant εᵣ of the material of the focus ring 17, and the projected area S and length (thickness) d in the axial direction thereof (εₒ is a dielectric constant in vacuum)

R=ρ*d/S (1)

X=−1/C*ω=−1/(εₒ*εᵣ*S/d)*ω (2)

Since the impedance Z of the material of the focus ring 17 consists of component R and component X, the material of the focus ring 17 can be expressed as an equivalent circuit shown in FIG. 2. Since this equivalent circuit is a parallel circuit having two current paths, it is converted into a series circuit having one current path to be normalized. If the value of resistance, electrostatic capacity and reactance in the parallel circuit of the material are defined as Rp, Cp and Xp, respectively, and if the value of resistance and reactance therein after being normalized are defined as Rs and Xs, respectively, converting expressions are expressed by expressions (3) and (4).

Rs=Rp/(1+ω²*Cp²* Rp²) (3)

Xs=−ω*Cp*Rp²/(1+ω²*Cp²*Rp² ) (4)

Therefore, using materials having physical values (specific resistanceρ, relative dielectric constantεᵣ, electrostatic capacity Cp) shown in the following table, i.e. silicon (Si), two kinds of silicon carbides (SiC-1, SiC-2) having different specific resistance, zirconium oxide (ZrO₂) and aluminum nitride (AlN), focus rings were produced.

The impedance Z of the focus ring of each material after being normalized was obtained to be shown in the following table. The following table also shows other physical values with respect to the wafer 8.

| | | | parallel | parallel | parallel | series | series | normal |
|---|---|---|---|---|---|---|---|---|
| | ρ | | Cp | Rp | Xp | Rs | Xs | -ized Z |
| | [Ωm] | εᵣ | [pF] | [Ω] | [jΩ] | [Ω] | [jΩ] | [Ω] |
| Wafer | 0.02 | 12 | 4760 | 4.5 × 10⁻⁴ | −0.56 | 4.5 × 10⁻⁴ | −3.6 × 10⁻⁷ | 0.0004 |
| Si | 0.02 | 12 | 200 | 1.1 × 10⁻² | −14 | 1.1 × 10⁻² | −8.7 × 10⁻⁶ | 0.01 |
| SiC-1 | 5 × 10² | 18 | 290 | 2.7 × 10² | −9.1 | 3.0 × 10⁻¹ | −9.05 | 9.05 |
| SiC-2 | 5 × 10⁵ | 18 | 290 | 2.7 × 10⁵ | −9.1 | 3.0 × 10⁻⁴ | −9.05 | 9.0 |
| ZrO₂ | 7 × 10⁵ | 30 | 490 | 3.8 × 10⁵ | −5.4 | 7.7 × 10⁻⁵ | −5.44 | 5.44 |
| AlN | 1 × 10⁷ | 7 | 110 | 5.4 × 10⁶ | −23 | 9.9 × 10⁻⁶ | −23.3 | 23.3 |

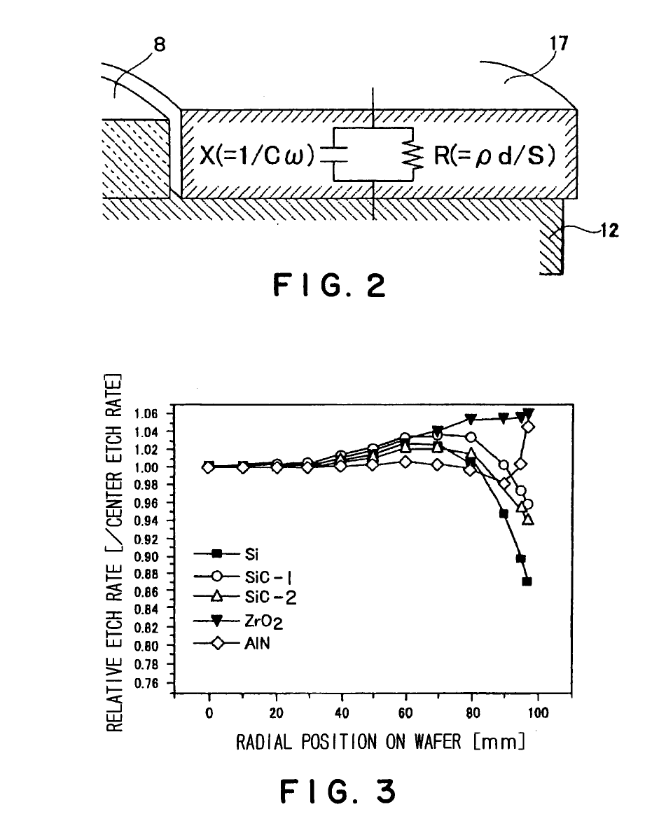

Using the focus ring of each material thus produced, a blanket-silicon oxide film of the wafer 8 was etched on the following processing conditions A. The etch rate of each portion of the wafer 8 was measured, and the results of the measurement is shown in FIG. 3.

[Processing Conditions A]

Diameter of Wafer: 200 mm

Etching Film: blanket-silicon oxide film

Top Electrode: power supply frequency=60 MHz, applied power=1500 W

Bottom Electrode: power supply frequency=2 MHz applied power=1600 W

Gap between Electrode: 25 mm

Processing Pressure: 20 mTorr

Process Gas (Flow Rate): C₄F₈ (8 sccm), Ar (300 sccm), O₂ (8 sccm)

As the results shown in FIG. 3, in the case of the conventional focus ring of Si, the etch rate deteriorates on the outer peripheral region of the wafer 8. On the other hand, in the focus rings of materials other than Si, the etch rates on the outer peripheral region of the wafer 8 are higher than that in the case of Si. Because it is considered that the impedance Z of these materials is hundreds to thousands times as high as that of Si so that it is difficult for a high frequency current to flow through the materials.

In the cases of the focus rings of SiC-1 and SiC-2, the resistance Rs of the latter is thousands times as high as that of the former, but the etch rate hardly changes. Because it is considered that the reactance Xs defining capacitive more greatly controls the flow of the high frequency current than the resistance Rs so that only the resistance Rs does not greatly change the impedance Z.

In the case of the focus ring of ZrO₂, the impedance Z is slightly lower than that in the case of SiC-2, but the etch rate on the outer peripheral region of the wafer 8 is conversely higher. Because it is considered that impedance Z as well as reactance Xs contributes to the etch rate by another function.

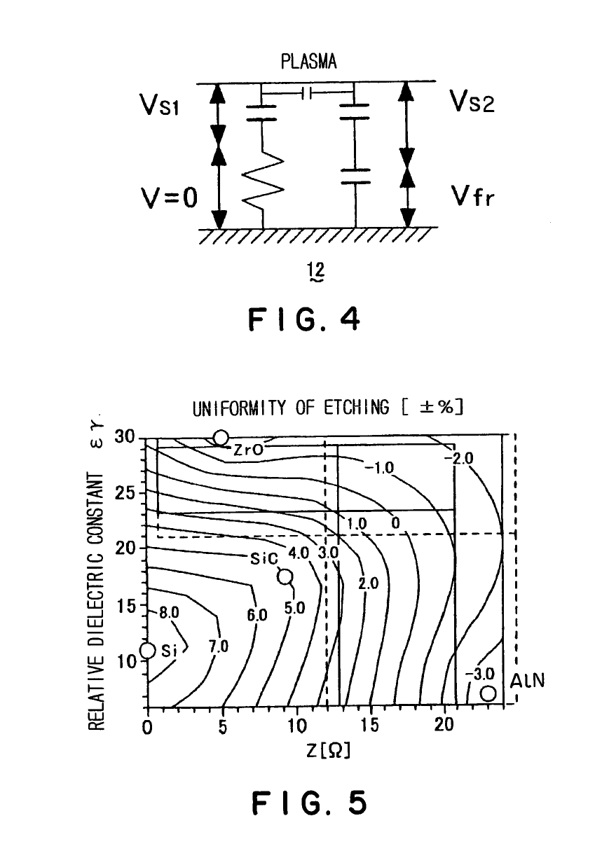

The influence of reactance Xs will be considered below. In a sheath region formed between the focus ring 17, the wafer 8 and plasma, an equivalent circuit shown in FIG. 4 is considered. In FIG. 4, Vₛ₁ denotes a sheath voltage above the wafer, V denotes the voltage of the wafer, Vₛ₂ denotes a sheath voltage above the focus ring, and V_{fr} denotes the voltage of the focus ring. The reason why the voltage of the wafer V=0 is that it is considered that it is almost short-circuited to the bottom electrode 12 since the resistance Rp of the wafer is far smaller than that of other materials. As can be clearly seen from FIG. 4, expression (5) is established between two portions each corresponding to the wafer 8 and the focus ring 17 on the bottom electrode 12.

Vₛ₁=Vₛ₂+V_{fr} (5)

From the relationship of V=Q/C (Q is charge due to electrons entering the bottom electrode 12, and is constant), V_{fr} decreases as the electrostatic capacity C of the focus ring 17 increases, and Vₛ₂ increases to approach Vₛ₁ as the electrostatic capacity C increases. Since the sheath voltage V_{edge} on the outer peripheral region of the wafer is an intermediate value between Vₛ₁ and Vₛ₂, V_{edge} increases as the electrostatic capacity of the focus ring 17 increases, so that the etch rate increases. Therefore, it can be seen from this that the etch rate on the outer peripheral region of the wafer increases as the capacitive of the focus ring 17 increases. Accordingly, it can be seen that the reactance Xs as well as the impedance Z of the focus ring 17 influences the etch rate on the outer peripheral region of the wafer.

The relationship between the impedance Z (Ω) and relative dielectric constantεᵣ of the focus ring of each material shown in the above table, and the uniformity (±%) of etch rate was obtained, and the results thereof is shown by o in FIG. 5. Minus values in FIG. 5 show that the etch rate on the outer peripheral region of the wafer is higher than that on the central region thereof. Plus values show that the etch rate on the outer peripheral region of the wafer is lower than that on the central region thereof. From the results shown in FIG. 5, the numerical value indicating the uniformity decreases to the minus side as the impedance Z and/or relative dielectric constant εᵣ increases. That is, there is a tendency for the etch rate on the outer peripheral region of the wafer to be higher than that on the central region thereof. Conversely, the numeric value indicating the uniformity increases to the plus side as the impedance Z and/or relative dielectric constant εᵣ decreases. That is, there is a tendency for the etch rate on the outer peripheral region of the wafer to be lower than that on the central region thereof.

Among the above described processing conditions and materials, the uniformity was best in the case of the focus ring of ZrO₂, and was between −2.0% and −3.0%. The uniformity in the case of AlN was good next to that in the case of ZrO₂, and was between −3.0% and −4.0%. However, the uniformity in the case of the focus ring of SiC was about +5.0%, and was inferior to the preceding two cases. It can be seen that the uniformity in the case of the conventional focus ring of Si exceeds 8.0%.

In view of the scale down in future, the uniformity of etch rate is preferably ±4.0% or less, more preferably ±3.0% or less. For example, in the case shown in FIG. 5, if the material of the focus ring is a material in the range surrounded by broken lines in which the impedance Z in the range of 1 to 25 Ω and the relative dielectric constant εᵣ is in the range of 21 to 30, or a material in the range surrounded by other broken lines in which the impedance Z is in the range of 12 to 25 Ω and the relative dielectric constant εᵣ is in the range of 5 to 30, the uniformity of ±4.0% or less can be obtained. If the material of the focus ring is a material in the range surrounded by solid lines in which the impedance Z is in the range of from 1 to 21 Ω and the relative dielectric constantεᵣ is in the range of 23 to 29, or a material in the range surrounded by other solid lines in which the impedance Z is in the range of from 13 to 21 Ω and the relative dielectric constant εᵣ is in the range of 5 to 29, the uniformity of ±3.0% or less can be obtained.

As examples of materials of focus rings having such physical properties, zirconium oxide and aluminum nitride are preferably used. There are also used a bonded article of a ring of zirconium oxide bonded to a ring of aluminum nitride, a composite composed of zirconium oxide and silicon carbide, and a composite composed of aluminum nitride and silicon carbide. The composites include, of course, the above described bonded article of at least two kinds of rings, each of which is made of a single material, and also include a bonded article of two kinds of composites, each of which is made of a plurality of materials. In order to control the projected area S and/or length (thickness) d in the axial direction of the focus ring so as to realize a desired impedance Z, the dimension and shape thereof may be changed.

In view of the foregoing, a plasma processing method according to the present invention is carried out through the following steps using the plasma processing system 10 with the above described construction.

(a) First, the focus ring 17 having a certain material, dimension and shape is used for etching the wafer 8 on certain processing conditions (for example, the above described processing conditions A).

(b) Then, there is prepared a new focus ring 17 wherein at least one of the material, dimension and shape is changed as follows on the basis of the etch rate distribution on the wafer 8 obtained as the results of the etching:

(b-1) if the etch rate on the outer peripheral region of the wafer 8 is lower than that on the central region thereof, the impedance Z and/or relative dielectric constant εᵣ of the focus ring 17 is increased in accordance with the difference in the etch rate between the two regions, and

(b-2) if the etch rate on the outer peripheral region of the wafer 8 is higher than that on the central region thereof, the impedance Z and/or relative dielectric constantεr of the focus ring 17 is decreased in accordance with the difference in the etch rate between the two regions.

(c) Then, the new focus ring 17 thus prepared is used for etching other wafers 8 on the processing conditions at the above described step (a).

According to the results of etching at the above described step (c), the steps (b) and (c) may be repeated. On the other hand, if the results at step (c) are satisfied, the changed focus ring 17 may be used for repeating only the step (c) required times.

According to such a plasma processing method in this preferred embodiment, the difference in field intensity between the outer peripheral region and central region of the wafer 8 due to the influence of the focus ring 17 can be decreased to uniformly etch the wafer 8.

The material of the focus ring for use in the present invention should not be limited to those in the above described preferred embodiment, but it may be a composite prepared by mixing or bonding various materials with or to each other, if necessary. While etching has been described as an example in this preferred embodiment, the present invention may be applied to another plasma processing.

Second Preferred Embodiment

Referring to FIGS. 1 and 6 through 10, the second preferred embodiment of the present invention will be described below.

Since a plasma processing system in this preferred embodiment basically has the same construction as that of the system in the first preferred embodiment shown in FIG. 1, the same reference numbers are given to the same components, and the duplicated descriptions are omitted.

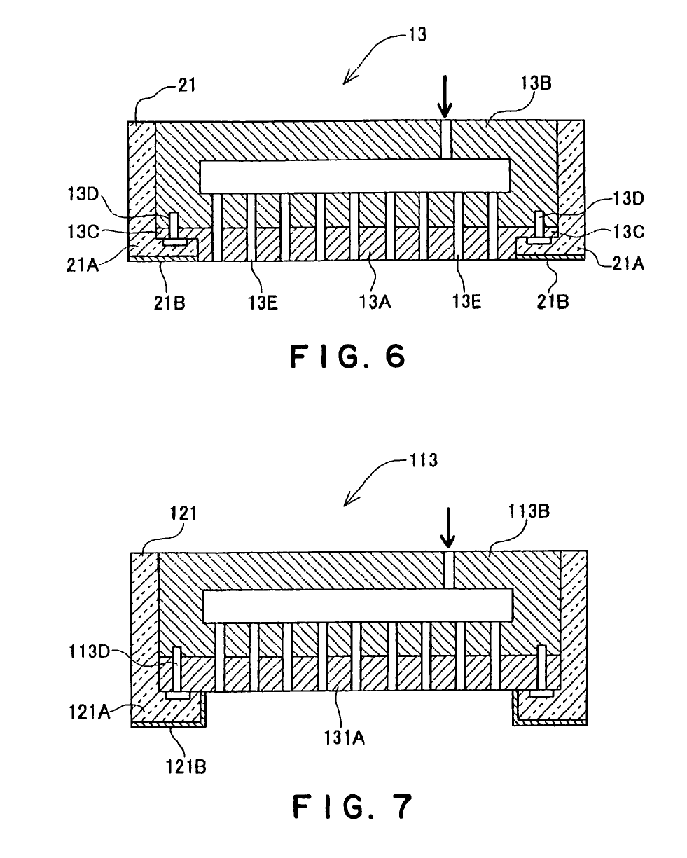

As shown in FIG. 6, for example, a top electrode 13 in this preferred embodiment has a plate-like electrode member 13A of silicon, and a hollow supporting body 13B of aluminum for detachably supporting thereon the electrode member 13A. A thin wall portion 13C is formed so as to extend radially outwardly from the periphery of the electrode member 13A over the whole circumference thereof. The electrode member 13A is secured to the supporting body 13B in the thin wall portion 13C by means of a plurality of bolts 13D. The bolts 13D are arranged at regular intervals in circumferential directions of the thin wall portion 13C.

A shield ring 21 is mounted on the top electrode 13. The shield ring 21 is formed of an inorganic oxide, such as quarts or alumina (quarts is used in this preferred embodiment). The shield ring 21 covers the outer peripheral surface of the top electrode 13 and the thin wall portion 13C of the electrode member 13A, and is arranged on the same plane as that of the electrode member 13A at the bottom face of the top electrode 13.

A portion of the shield ring 21 covering the thin wall portion 13C of the electrode member 13A is formed as a flange portion 21A. The bottom face of the flange portion 21A is covered with a plasma-resistant film 21B so that the shield ring 21 does not directly contact plasma. The plasma-resistant film herein means a film producing no oxygen and contaminants even if ions attack on the film.

The plasma-resistant film 21B is formed of an oxide of a rare-earth element, such as yttrium oxide (Y₂O₃), or a heat-resistant resin, such as a polyimide resin. The yttrium oxide film can be formed so as to have a suitable thickness by means of atmospheric-plasma thermal-spraying of yttrium oxide. The thickness is preferably in the range of from 100 to 500 μm although it should not particularly be limited. As the film of the polyimide resin, a pressure sensitive adhesive tape of a polyimide resin is preferably used. Similar to quarts, yttrium oxide contains oxygen atoms in its crystal structure. However, since the bond energy of yttrium atom and oxygen atom is high and stable, even if ions attack on yttrium oxide, the bond of Y—O is difficult to be open, so that it is possible to particularly inhibit dissociation of oxygen atoms.

Therefore, even if ions attack on the shield ring 21 of the top electrode 13, it is possible to particularly inhibit the generation of oxygen from the shield ring 21. For that reason, on the outer peripheral region of the wafer 8, there is not the possibility that the etch rate of the resist film rises by oxygen plasma unlike conventional systems, so that the etch rate of the resist film over the wafer 8 can be uniform. In other words, it can be seen that plasma on the outer peripheral region of the wafer 8 contains oxygen-rich when the etch rate of the resist film on the outer peripheral region of the wafer 8 rises. For example, when the silicon oxide film is etched with fluorocarbon gas (CₓF_{y}), if the shield ring 21 is coated with the plasma-resistant film 21B, the etch rate of the resist film can be uniform without causing plasma on the outer peripheral region of the wafer 8 to be oxygen-rich.

Moreover, if plasma on the outer peripheral region of the wafer 8 is oxygen-rich, the etch rate of the resist film in this region increases, and the following phenomenon is caused. That is, on the outer peripheral region of the wafer 8, a CF polymerized substance being a side wall protective film in the hole of the silicon oxide film dug by etching, or CF ions in plasma in the hole react with oxygen to generate CO and CO₂. Thus, on the outer peripheral region of the wafer 8, plasma in the hole becomes fluorine- rich to relatively increase the etch rate of the silicon oxide film, so that the spreading of the hole side wall proceeds. Therefore, in the silicon oxide film on the wafer 8, the uniformity of the etch rate deteriorates, so that the shape thereof deteriorates by etching.

In this preferred embodiment, since plasma on the outer peripheral region of the wafer 8 does not become oxygen-rich due to the effects of the plasma-resistant film 21B, the etch rate of the resist film as well as the etch rate itself of the silicon oxide film can be uniform. As a result, etching can form a vertical side wall in the hole of the silicon oxide so as to extend over the whole surface of the wafer 8.

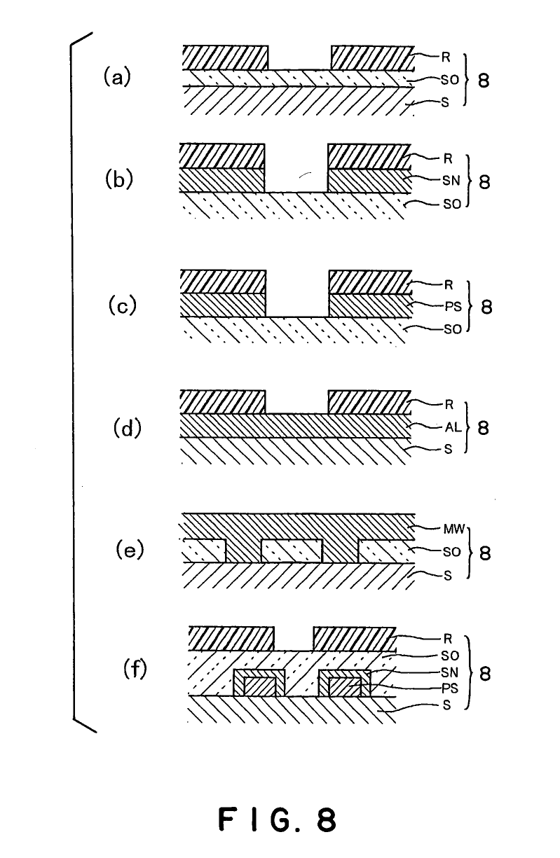

For example, when the silicon oxide film is etched, there are forms shown in (a) through (f) of FIG. 8 (alphabets used in FIG. 8 are different from chemical formulae).

The wafer 8 shown in FIG. 8(a) has a silicon oxide film SO and a resist film R on a silicon S. When the silicon oxide film SO of the wafer 8 is etched, the resist film R is etched in accordance with a certain pattern. At this time, since it is difficult for oxygen to be generated from the shield ring 21 in this preferred embodiment, the etch rate of the resist film R can be uniform over the whole surface of the wafer 8, and the silicon oxide film SO can be uniformly etched to form a vertical side wall. Particularly, when the silicon oxide film R is BPSG, bowing is easy to occur due to the influence of oxygen, but it is possible to prevent bowing in this preferred embodiment.

The wafer 8 shown in FIG. 8(b) has a silicon nitride film SN and a resist film R on a silicon oxide film SO, and the wafer 8 shown in FIG. 8(c) has a polysilicon film PS and a resist film R on a silicon oxide film SO. Also in these cases similar to the wafer 8 shown in FIG. 8(a), the etch rate of the resist film R can be uniform over the whole surface of the wafer 8, and the silicon oxide film SO can be uniformly etched.

The wafer 8 shown in FIG. 8(d) has an alloy layer AL of aluminum, silicon and copper and a resist film R on silicon S. In this case, it is possible to inhibit the alloy film AL from being oxidized on the outer peripheral region of the wafer 8.

The wafer 8 shown in FIG. 8(e) has a silicon oxide film SO and a tungsten film MW on silicon S. When the tungsten film MW of the wafer 8 is etched back, it is possible to inhibit tungsten from being oxidized on the outer peripheral region of the wafer 8.

The wafer 8 shown in FIG. 8(f) has a polysilicon film PS coated with a silicon nitride film SN, a silicon oxide film SO and a resist film R on silicon S. Also when the self-aligning contact (SAC) etching of the wafer 8 is carried out, the influence of oxygen can be inhibited, so that the etch rate of the resist film R can be uniform over the whole surface of the wafer 8 to uniformly carry out the SAC etching.

As described above, according to this preferred embodiment, since the contact portion of the shield ring 21 of quarts to plasma is coated with the plasma-resistant film 21B, so that it is possible to prevent oxygen from being generated by the attaching of ions on the shield ring 21 when a plasma processing, such as etching, is carried out. Therefore, there is not the possibility that plasma above the outer peripheral region of the wafer 8 is oxygen-rich, so that it is possible to prevent the etch rate of the resist film from rising on the outer peripheral region of the wafer 8. Thus, the etch rate of the resist film on the wafer 8 can be uniform, so that the etch rate and shape of the silicon oxide film on the wafer 8 can be uniform.

FIG. 7 shows a modified example of the top electrode 13 shown in FIG. 6. A top electrode 113 shown in FIG. 7 has an electrode member 113A of silicon, a supporting body 113B and a shield ring 121, and is the same as that shown in FIG. 6, except that the shape of the electrode member 113A and shield ring 121 is different. The electrode member 113A is formed so as to have the uniform thickness as a whole. A plurality of bolts 113D, for connecting the electrode member 113A to the supporting body 113B, is covered with the flange portion 121A of the shield ring 121. The flange portion 121A is different from that shown in FIG. 6 at the point that there is a difference in level between the flange portion 121A and the bottom face of the electrode member 131A to form a stepped portion. The bottom face of the flange portion 121A and the inner peripheral surface in the stepped portion, i.e. the portion contacting plasma, are coated with the plasma-resistant film 121A. Also in this case, it is possible to inhibit oxygen from being generated from the shield ring 121 during the plasma processing, so that it is possible to expect the same effects.

Examples in this preferred embodiment will be described below.

### EXAMPLE 1

In this example, a thermal-sprayed film of yttrium oxide is used as the plasma-resistant film 21B. On the following processing conditions B, the distance between the bottom electrode 12 and the top electrode 13 was set to be 21, 25 and 35 mm to carry out etching, and the etch rate of the resist film in each case was measured. The results thereof are shown in FIG. 9.

[Processing Conditions B]

Diameter of Wafer: 200 mm

Resist Film: Kr-F resist film

Film to be etched: silicon oxide film

Contents of Processing: Formation of Contact Hole

Top Electrode: power supply frequency=60 MHz, applied power=1500 W

Bottom Electrode: power supply frequency=2 MHz applied power=1600 W

Processing Pressure: 20 mTorr

Process Gas (Flow Rate): C₄F₈ (8 sccm), Ar (300 sccm), O₂ (8 sccm)

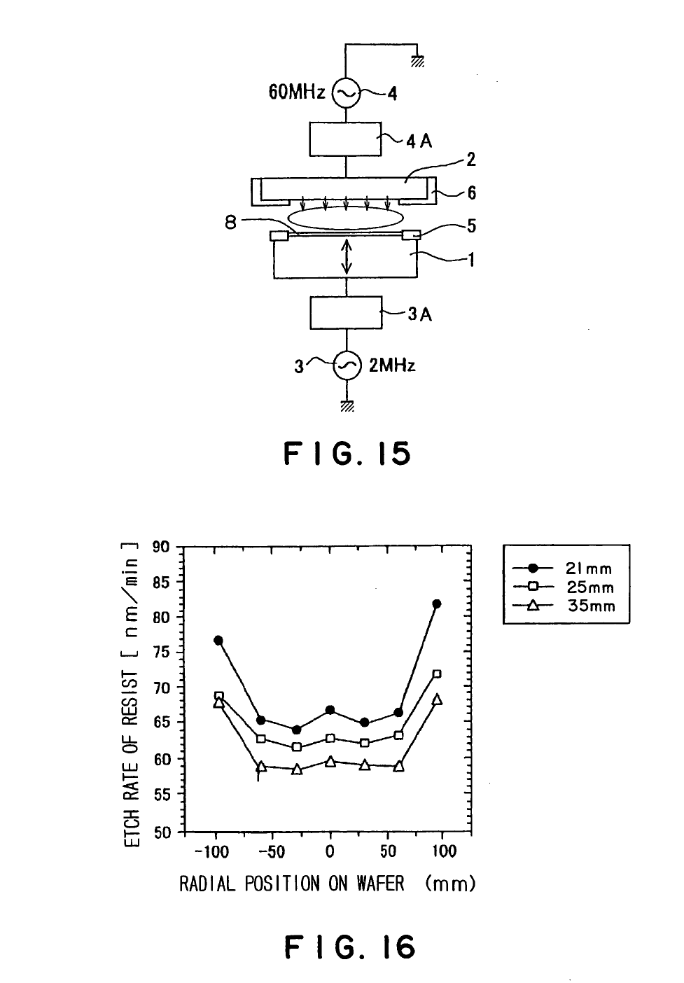

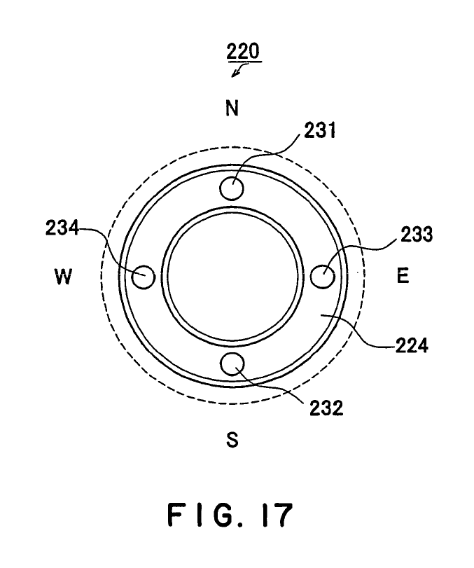

From the results shown in FIG. 9, it can be seen that the rise in etch rate in the outer peripheral region of the wafer 8 is inhibited as compared with the results of the conventional plasma processing system (having no plasma-resistant film) shown in FIG. 16 and that the etch rate of the resist film on the wafer 8 is uniform. Also as can be clearly seen from this, by coating the shield ring 21 with the plasma-resistant film 21B, it is possible to inhibit oxygen from being generated above the outer peripheral region of the wafer 8, and it is possible to particularly inhibit the bad influence of oxygen on etching.

### EXAMPLE 2

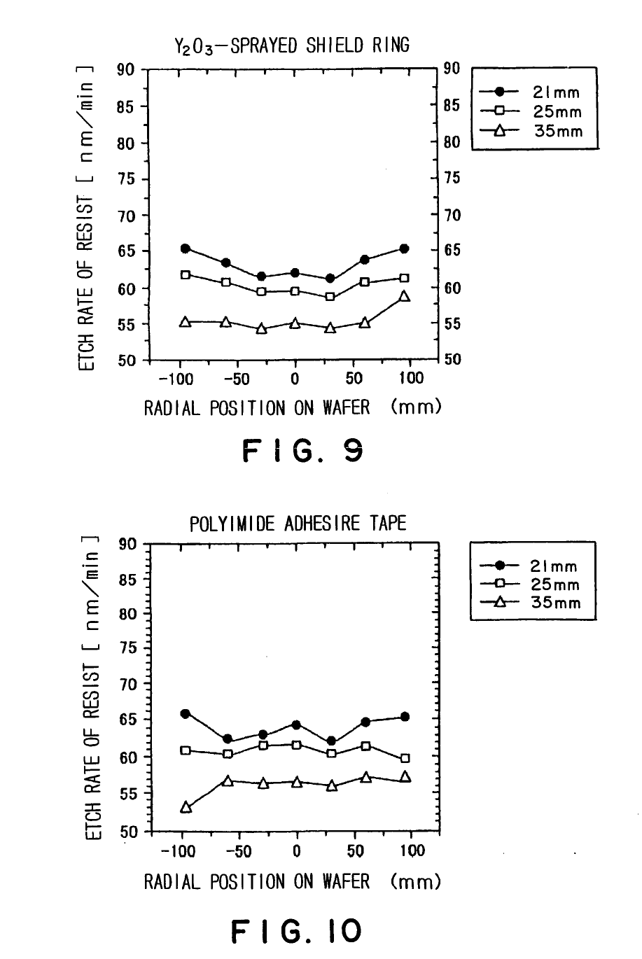

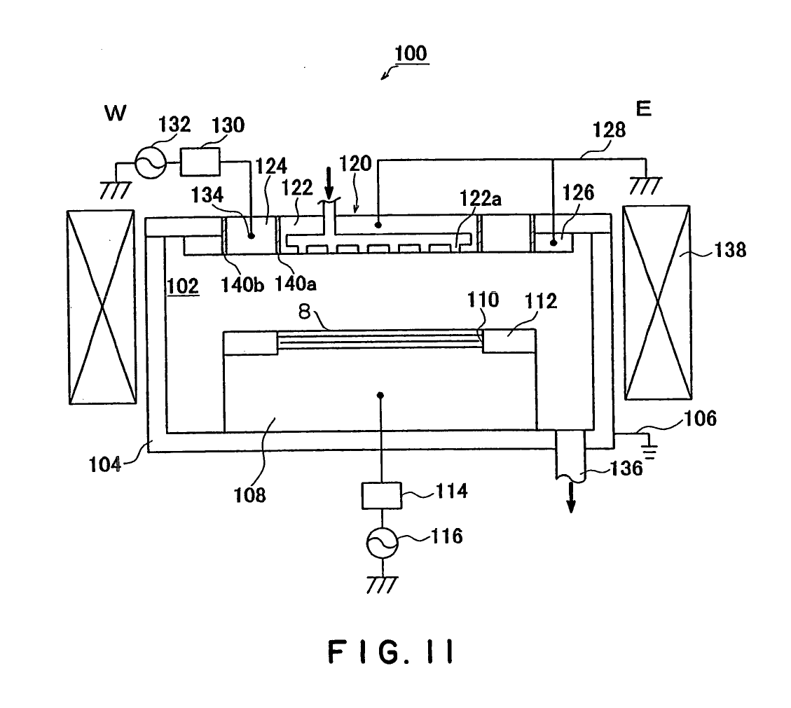

In this example, the same measurement as that in Example 1 was carried out by using a polyimide film (specifically Capton (tread mark) tape) as the plasma-resistant film 21B. As shown in FIG. 10. The same effects as those in Example 1 can be obtained in this example.

While the thermal-sprayed film of yttrium oxide or the polyimide film have been used as the plasma-resistant film in this preferred embodiment, the present invention should not be particularly limited if the shield ring is coated with the plasma-resistant film capable of inhibiting the generation of oxygen.

While the shield ring of quarts has been used in this preferred embodiment, the present invention should not be particularly limited if the shield ring is made of an inorganic oxide emitting oxygen when it is exposed to plasma.

While the etching has been carried out in this preferred embodiment, the present invention can be applied to other kind of plasma processing, such as CVD.

When the protective cover and focus ring mounted on the bottom electrode are formed of an inorganic oxide, such as quarts, these members may be coated with the plasma-resistant film to expect the same effects as those in the case of the shield ring.

Third Preferred Embodiment

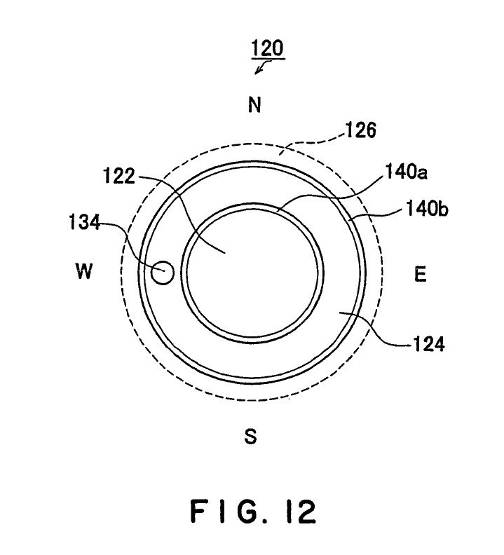

Referring to FIGS. 11 through 14, the third preferred embodiment of the present invention will be described below.

In this preferred embodiment, the same reference numbers are given to components having the same functions and constructions, and duplicated descriptions are omitted.

FIG. 11 is a sectional view of a plasma processing system in this preferred embodiment, taken in a direction through W-pole and E-pole of a magnetic field due to a magnet 138 which will be described later. A plasma processing system 100 shown in FIG. 11 comprises a cylindrical processing vessel 104 for defining a processing chamber (plasma processing chamber) 102. The processing vessel 104 is capable of being air-tightly closed, and is made of aluminum with anode oxidation coating. The processing vessel 104 is grounded by means of a grounding cable 106.

In the processing chamber 102, a conductive bottom electrode 108 also used as a table for supporting thereon the wafer 8 is arranged. On the supporting surface of the bottom electrode 108, an electrostatic chuck 110 for attracting and holding the wafer 8 is provided. The electrostatic chuck 110 has such a structure that a conductive thin film is sandwiched between polyimide resins. If a voltage is applied to the thin film from a DC power supply (not shown) installed outside of the processing vessel 104, the wafer 8 is attracted and held by the Coulomb force. The wafer 8 may be held by pressing the peripheral portion of the wafer 8 by means of, e.g. a mechanical clamp, without the need of the electrostatic chuck 110.

On the bottom electrode 108, a focus ring 112 is provided so as to surround the electrostatic chuck 110. The focus ring 112 is formed of an insulating material, such as quarts, and has the function of improving the uniformity of the etch rate on the outer peripheral region of the wafer 8.

The bottom electrode 108 is connected to a second high frequency power supply 116 via a second matching device 114. A high frequency power (50 to 2500 w) of a certain frequency (e.g. 13.56 MHz) is applied to the bottom electrode 108. With this construction, a process gas is made to be plasma, and a bias potential is applied to the bottom electrode 108 supporting thereon the wafer 8 during a plasma processing, so that etchant in plasma can be efficiently injected into the surface of the wafer 8.

In the processing chamber 102, a conductive top electrode 120 facing the supporting surface of the bottom electrode 108 is arranged so as to form a ceiling wall of the processing chamber 102.

Also as shown in FIG. 12, the top electrode 120 in this preferred embodiment comprises a substantially disk-shaped top central electrode 122, and a top ring electrode 124 surrounding the outer periphery of the central electrode 122. Around the top ring electrode 124, a top focus ring 126 for improving the uniformity of the etch rate on the outer peripheral region of the wafer 8 is arranged. The top central electrode 122, the top ring electrode 124 and the top focus ring 126 are made of aluminum with anode oxidation coating. Between the top central electrode 122 and the top ring electrode 124, and between the top ring electrode 124 and the top focus ring 126, first and second insulating rings (insulators) 140a and 140b of, e.g. quarts, are inserted, respectively. The top central electrodes 122 and the top focus ring 126 are grounded by a grounding cable 128.

Unlike conventional systems, in the top ring electrode 124 in this preferred embodiment, the feeding from the high frequency power supply is carried out only at the W-side feeding point 134 with respect to the above described magnetic field. That is, only the W-side feeding point 134 is connected to the first high frequency power supply 132 via the first matching device 130 to apply a high frequency power (50 to 1000 w) of a certain frequency (e.g. 100 MHz) to the top ring electrode 124. Thus, the high frequency power from the first high frequency power supply 132 is fed only to the W-side feeding point, so that a stronger electric field can be generated on the W-side of the top electrode 120 than another pole side as will be describe later.

The top central electrode 122 has a plurality of gas discharging holes 122a, and a process gas, containing e.g. Ar, C₄F₈ and/or CF₄ gases, is fed into the processing chamber 102 from gas supply sources (not shown) via flow regulating valves (not shown), shut-off valves (not shown) and the gas discharging holes 122a. The gas fed into the processing chamber 102 is exhausted by a vacuum pump (not shown), such as a turbo molecular pump, via an exhaust pipe 136 provided in the bottom of the processing chamber 102, and the processing chamber 102 can be evacuated to an optional degree of vacuum.

Around the outer periphery of the processing chamber 102, a permanent magnet (e. g. a dipole ring magnet) 138 serving as a magnetic field forming means for forming a magnetic field in the processing chamber 102 is arranged. By this magnet 138, a magnetic field being in parallel to the surface of the wafer 8 and having a certain polarity is formed.

Referring to FIG. 13, a magnetic field distribution on the wafer 8 formed by the magnet 138 will be described below.

FIG. 13 shows a magnetic field distribution obtained by actually measuring a magnetic field formed on the wafer 8, by vectors and isointensity lines of the magnetic field on the wafer 8, in a plasma processing system in this preferred embodiment. The magnetic field distribution shown in FIG. 13 is basically the same as a magnetic field distribution formed by a conventional plasma processing system.

As shown in FIG. 13, it can be seen that a magnetic field is formed on the wafer from N-side to S-side, and that the interval between adjacent isointensity lines of the magnetic field on the E-side is narrower than that on the W-side. This shows that the intensity of the magnetic field formed on the E-side is stronger than the intensity of the magnetic field on the W-side. In other words, since the intensity of the magnetic field on the W-side is weaker than the intensity of the magnetic field on the E-side, the acceleration of electrons toward the E-side is reduced in the vicinity of the bottom face of the top electrode on the W-side. That is, the E×B drift effect is reduced as the whole plasma processing system.

Therefore, in this preferred embodiment, a construction for feeding from the high frequency power supply only to the W-side feeding point 134 of the top ring electrode 122 is adopted in order to compensate for the relatively low density of a magnetic field formed on the W-side. With this construction, a strong magnetic field compensating for the relatively low density of the magnetic field is formed on the W-side, so that the E×B drift effect can be improved.

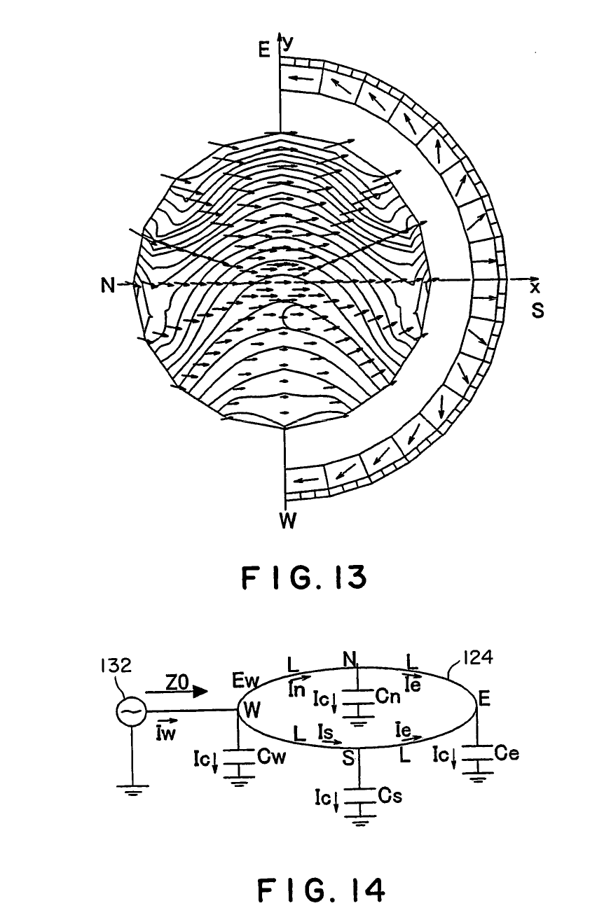

Referring to FIG. 14, the principle that the relatively strong electric field is generated on the W-side by feeding only to the W-side feeding point of the top ring electrode will be described below.

First, as shown in FIG. 14, the top ring electrode 124 in this preferred embodiment can be regarded as an LC circuit having a parasitic inductance L and a parasitic capacity C since a high frequency power is applied thereto. In this case, the parasitic inductance L is a self-inductance L of the top ring electrode 124 itself. The parasitic capacity C corresponds to insulators 140a, 140b (see FIG. 12) between the top ring electrode 124 and GND (i.e. the top central electrode 122 and the top focus ring 126) and a plasma sheath region.

The sheath region means a region in which the neutral of plasma is broken and which is formed by the fact that electrons having a higher moving speed than that of ions in plasma adhere to the vicinity of the surface of members or wafer prior to the adhesion of ions.

It is considered that such an LC circuit (ring electrode 124) is an LC low pass filter circuit wherein power is inputted on the W-side and outputted on the E-side, since the parasitic capacity C of the insulator acts as a filter at high frequencies. Mainly by the parasitic capacity C of the insulator, the transmission efficiency of current is damped on the output side. This will be described below.

In the above described LC circuit (top ring electrode 124), the intensity E of the electric field generated on each pole side is expressed as follows (subscripts w, n, s and e correspond to each pole of W, N, S and E).

W-pole side:Ew=Iw*(Z0−1/Cw*ω)

N-pole side:En=In*(Z0+L*ω−1/Cn*ω)

S-pole side:Es=Is*(Z0+L*ω−1/Cs*ω)

E-pole side:Ee=Ie*(Z0+2*L*ω−1/Ce*ω)

(Z0: impedance from power source to W-side, L: self-inductance, C: parasitic capacity, I: current passing to each pole side)

In this case, if a high frequency current is fed to the W-side feeding point of the top ring electrode 124, the impedance of the parasitic capacity formed by the insulator decreases. Thus, the current flowing from the parasitic capacity C to GND increases, and power is consumed in the parasitic capacity C. Since such a parasitic capacity C has a resistance component R, the current and the power passing on the downstream side (S-side, N-side and E-side) decrease.

2Ie=Iw−2*Ic

(Ic: current passing through parasitic capacity)

Pe=Pw−2* Ic²*Rc

(P: power on each pole side, Rc: resistance of parasitic capacity)

In this case, since inductive reactance (Lωj) also increases, the transmission of current flowing from the upstream side (W-side) to the downstream side (E-side) is prevented. Therefore, the current flowing to the E-side (output side) is lower than the current on the W-side. As a result, the current Ie flowing on the E-side is smaller than the current Iw fed to the W-side (i.e. Iw>In=Is>Ie). Therefore, the electric field formed on each pole is relatively strong on the W-side and weak on the E-side (i.e. Ew>En=Es>Ee).

Thus, since the parasitic capacity C of the insulator particularly acts as a filter, the relatively stronger electric field on the W-side than the E-side can be generated by feeding only to the W-side feeding point of the top ring electrode.

In an example where the oxide film (SiO₂) of the silicon wafer 8 is etched by means of the plasma processing system with the above described construction, its operation, function and so forth will be described below.

First, after the wafer 8 is mounted on the electrostatic chuck 110, the processing chamber 102 is being evacuated by an evacuating means (not shown). Then, the pressure in the processing chamber 102 is a certain reduced pressure, process gases (e.g. C₄F₈ gas, CO gas, Ar gas, O₂ gas) are fed into the processing chamber 102 from a process gas supply source (not shown) so that the pressure in the processing chamber 102 is maintained at a set pressure of, e.g. 40 mTorr.

Then, a high frequency power of, e.g. 13.56 MHz and 1500 watt is applied to the bottom electrode 108 from the second high frequency power supply 116. A high frequency power of, e.g. 100 MHz and 300 watt is applied only to the W-side feeding point 134 of the top ring electrode 124 from the first high frequency power supply 132 to excite plasma in the processing chamber 102. The electric field between the electrodes 108 and 120 and the magnetic field vertically crossing the electric field are associated with each other for forming a transverse electromagnetic field in a plasma region. In this case, as described above, the magnetic field formed in the processing chamber 102 by the magnet 138 is formed so that the magnetic field density on the W-side is lower than that on the E-side. The distance between the electrodes is set to be 27 mm.

When the second high frequency power supply 116 applies a voltage to the bottom electrode 108 supporting thereon the semiconductor wafer 8, electrons in plasma reach to the wafer 8 prior to ion particles, so that the wafer 8 is charged to be negatively self-biased. Thus, a large potential difference is caused between the plasma voltage and the self-bias voltage of the wafer 8, so that a sheath region is formed between the plasma region and the surface of the wafer 8. In this preferred embodiment, since the voltage is applied only to the W-side feeding point 134 of the top ring electrode 124 as described above, the sheath region acts as the parasitic capacity C of the top electrode 120 to form a relatively weak electric field on the N, S and E-sides and a strong electric field on the W-side.

Thus, on the W-side, the relatively strong electric field is formed with respect to the relatively weak magnetic field. By such an electromagnetic field, electrons and ion particles in plasma make a cycloid motion in an elliptical region between both of the electrodes by the effective induction of the E×B drift motion, to form an uniform and high density plasma.

Then, ions in plasma rapidly flight in the sheath region by the potential difference and vertically collide against the surface of the semiconductor wafer 8. Thus, an reactive ion etching is carried out in accordance with a resist pattern formed on the surface of the semiconductor wafer 8. In this case, gases generated by etching are discharged to the outside via the outlet 136.

While the plasma processing system has been the system for etching the silicon oxide film on the surface of the semiconductor wafer of silicon in the above described preferred embodiment, other objects, such as LCD substrates, may be used as an object to be processed, and other kinds of etching may be carried out.

While the plasma processing system has been used as an etching system in the above described preferred embodiment, other plasma processing systems, such as ashing systems, sputtering systems and CVD systems, may be used.

While the top ring electrode has been comprised a single-structure ring electrode in the above described preferred embodiment, it may comprise a multiple-structure ring electrode having a plurality of coaxially arranged ring electrodes. In that case, the drift effect can be more effectively improved by feeding to a suitable position of each ring electrode.

1. A plasma processing method for processing an object to be processed with a plasma in a plasma processing system, said system comprising a pair of electrodes arranged in parallel to each other in a processing vessel, said object being held on one of said electrodes and surrounded by a focus ring provided on said one of said electrodes, said system producing said plasma between said pair of electrodes by applying a high frequency power to at least one of said electrodes, said plasma processing method comprising the steps of:
(a) carrying out a plasma processing on certain processing conditions with said focus ring having a certain material, dimension and shape;
(b) preparing a new focus ring wherein at least one of said material, dimension and shape is changed on the basis of results of said plasma processing so that,
(b-1) if a processing rate on an outer peripheral region of said object is lower than a processing rate on a central region of said object, an impedance and/or a relative dielectric constant of said focus ring is increased in accordance with the difference in said processing rate between said two regions, and
(b-2) if a processing rate on an outer peripheral region of said object is higher than a processing rate on a central region of said object, an impedance and/or a relative dielectric constant of said focus ring is decreased in accordance with the difference in said processing rate between said two regions; and
(c) carrying out another plasma processing on the same processing conditions as those at said step (a) with said prepared new focus ring.

2. A plasma processing method as set forth in claim 1, wherein said focus ring has a rectangular cross section, and said new focus ring having a changed projected area and/or length in an axial direction is prepared in said step (b).

3. A plasma processing method as set forth in claim 1, wherein said material of said focus ring is a composite including a plurality of materials.

4. A plasma processing method as set forth in claim 3, wherein said material of said focus ring is any one of a composite containing zirconium oxide, a composite containing aluminum nitride, and a composite containing silicon carbide.

5. A plasma processing method as set forth in claim 1, wherein an etching of an oxide film is carried out as said plasma processing.

6. A plasma processing system comprising:
a processing vessel;
a first electrode arranged in said processing vessel;
a second electrode, arranged in parallel to said first electrode in said processing vessel, for holding an object to be processed;
a high frequency power supply for applying a high frequency power to at least said first electrode; and
a shield ring of an inorganic oxide for covering at least an outer peripheral portion of a surface of said first electrode facing said second electrode,
said system producing a plasma between said first and second electrodes by applying said high frequency power by said power supply, to process said object with said plasma,
wherein a portion of said shield ring contacting said plasma is coated with a plasma-resistant film.

7. A plasma processing system for processing an object to be processed having a thin film coated with a resist film, said system etching said thin film in accordance with a shape of said resist film and comprising:
a processing vessel;
a first electrode arranged in said processing vessel;
a second electrode, arranged in parallel to said first electrode in said processing vessel, for holding said object;
a high frequency power supply for applying a high frequency power to at least said first electrode; and
a shield ring of an inorganic oxide for covering at least an outer peripheral portion of a surface of said first electrode facing said second electrode,
said system producing a plasma between said first and second electrodes by applying the high frequency power by said power supply, to etch said object with said plasma,
wherein a portion of said shield ring contacting the plasma is coated with a plasma-resistant film.

8. A plasma processing system as set forth in claim 6 or 7, wherein said plasma-resistant film is made of an oxide of a rare-earth element or a heat-resistant resin.

9. A plasma processing system as set forth in claim 8, wherein said rare-earth element is yttrium.

10. A plasma processing system as set forth in claim 8, wherein said heat-resistant resin is a polyimide resin.

11. A plasma processing system comprising:
a processing vessel;
a first electrode arranged in said processing vessel, said first electrode including a central electrode electrically grounded, and a high frequency electrode surrounding an outer periphery of said central electrode,
a second electrode, arranged in parallel to said first electrode in said processing vessel, for holding an object to be processed having a surface to be processed;
magnetic-field applying means for forming a magnetic field between said first and second electrodes, said magnetic field being parallel to said surface of said object and having a certain polarity; and
a high frequency power supply for applying a high frequency power to at least said high frequency electrode of said first electrode,
wherein a feeding from said high frequency power supply to said high frequency electrode is carried out only at a feeding point on a west side of said magnetic field on said high frequency electrode.

12. A plasma processing system as set forth in claim 11, said system further comprising a focus ring electrically grounded, said focus ring surrounding an outer periphery of said high frequency electrode of said first electrode.

13. A plasma processing system as set forth in claim 12, said system further comprising:
an first insulating member provided between said central and high frequency electrodes of said first electrode; and
an second insulating member provided between said high frequency electrode of said first electrode and said focus ring.

14. A plasma processing system as set forth in claim 11, wherein a plasma-producing and biasing high frequency power is applied to said second electrode.
